(19) United States
(12) Patent Application Publication
(10) Pub. No.: US 2011/0159177 A1
(43) Pub. Date: Jun. 30, 2011

(54) Coated Translucent Substrate For A Greenhouse And A Freezer Door

(76) Inventor: Petrus Antonius VAN NIJNATTEN, Deurne (NL)

(21) Appl. No.: 12/981,071

(22) Filed: Dec. 29, 2010

(30) Foreign Application Priority Data
Dec. 29, 2009 (NL) 2004024

(51) Int. Cl. B05D 5/06; C23C 14/34; A01G 9/14; C23C 16/44; G02B 5/20; G02B 1/11

(52) U.S. Cl. 427/161; 204/192.1; 47/17; 359/359

(57) ABSTRACT

An coated translucent substrate that comprises a translucent substrate, an anti-reflection coating and a conductive oxide coating and a process for manufacturing the same is provided. The translucent substrate has a first surface at a first side. The anti-reflection coating is provided at the first side of the translucent substrate to reduce the reflection of light by the coated translucent substrate. The anti-reflection coating is applied to the conductive oxide coating. The conductive oxide coating is arranged between the first surface of the translucent substrate and the anti-reflection coating to reduce the transmission of light in the near infrared spectrum through the coated translucent substrate. The conductive oxide coating comprises SnO₂:F. The coated translucent substrate transmits relatively good light in the Photosynthetically Active Radiation spectral range and blocks the light in the Near Infrared spectral range.

This application claims priority to Dutch application NL 2004024 filed 29 Dec. 2009.

### FIELD OF THE INVENTION

The invention relates to the field of translucent substrates for greenhouses and freezer doors and the manufacture of the same.

### BACKGROUND OF THE INVENTION

Glass with a coating to block the transmission of a part of the light in the Near Infrared (NIR) spectrum (roughly from 800 to 2500 nanometers in wavelength) is used in some greenhouses to prevent the transfer of the NIR light into the greenhouse. NIR light is not required for photosynthesis of plants in a greenhouse and substantially only result in increasing the temperature of the greenhouse. Plants have a temperature bandwidth in which their growth is optimal. If the temperature in the greenhouse exceeds the maximum temperature of the bandwidth, the temperature should be reduced. The simplest way to reduce the temperature in the greenhouse is ventilating the greenhouse. However, this is not preferred because of the loss of carbon dioxide. Relative high concentrations of carbon dioxide positively stimulate crop growth.

Known coatings that block the light in the NIR spectral range are, for example, silver (Ag) based low-emissivity coatings, or transparent conductive oxide coatings of, for example, ZnO₂:Al or an Indium Tin Oxide (ITO). The conductive oxide coatings are often used as transparent electrodes because of their conductivity. Silver based coatings are soft and have, for example, a disadvantage of oxidation when the coating is in contact with oxygen and with water in the air. Thus, a single glass substrate with silver is not possible. Furthermore, the material is relatively expensive. A silver based coating is often used in double glazing for buildings. The silver based coating is provided on one of the surfaces of one of the glass substrates in an argon gas filled air gap between the glass substrates to prevent the silver layer from degrading due to exposure to the ambient air. However, the construction of greenhouses is in general not designed for the weight of double glazing and double glazing is more expensive.

A further disadvantage of all the mentioned materials is that they block part of the light in the Photosynthetically Active Radiation (PAR) spectral range (roughly from 400 to 700 nanometers in wavelength) which is required for the photosynthesis of crops. Thus, a problem of the known glass substrates with a silver based low-emissivity coating or with a transparent conductive oxide coating is that they reduce the yield of greenhouses.

### SUMMARY OF THE INVENTION

It is an object of the invention to provide a translucent substrate that has an improved blocking of light in the Near Infrared light spectrum while maintaining relatively good transmission of light in the Photosynthetically Active Radiation spectral range and thus resulting in a good yield of the greenhouse.

A coated translucent substrate in accordance with the first aspect of the invention comprises a translucent substrate, an anti-reflection coating and a conductive oxide coating. The translucent substrate has a first surface at a first side. The anti-reflection coating is provided at the first side of the translucent substrate to reduce the reflection of light by the coated translucent substrate and the anti-reflection coating is applied to the conductive oxide coating. Further, the anti-reflection coating may comprise multiple layers. The conductive oxide coating is arranged between the first surface of the translucent substrate and the anti-reflection coating to reduce the transmission of light in the near infrared spectrum through the coated translucent substrate. The conductive oxide coating comprises SnO₂:F.

The translucent substrate may, for example, be made of glass. Furthermore, the translucent substrate may be diffuse, patterned or fully transparent. Both the anti-reflection coating and the conductive oxide coating are applied to a first side translucent substrate with the conductive oxide coating being closest to the translucent substrate. However, one or more other layers or coating may be interposed between the conductive oxide coating and the translucent substrate. The anti-reflection coating is directly applied to the conductive oxide coating. The conductive oxide coating and the anti-reflection coating are applied substantially parallel to the first surface and may, for example, substantially cover the whole first side of the translucent substrate. The conductive oxide coating reduces the transmission of light in the near infrared spectral range, which means that a substantial part of the light in the near infrared spectral range is reflected and/or absorbed by the conductive oxide coating.

The conductive oxide coating that comprises SnO₂:F reflects and absorbs a substantial part of the light in the near infrared spectral range. Further, the conductive oxide coating comprising SnO₂:F applied to a translucent substrate provides good thermal insulation because it has a thermal emissivity which is lower than the thermal emissivity of the translucent substrate without the coating. However, as with most known conductive oxide coatings, a part of the light in the Photosynthetically Active Radiation (PAR) spectral range is also reflected, significantly reducing the yield of the greenhouse. The inventor found that adding the anti-reflection coating on the SnO₂:F not only significantly reduces reflection of the light in the PAR spectrum, but also, surprisingly, increases the reflection of light in the near infrared spectral range. At the same time the anti-reflection coating has a negligible effect on the relatively low thermal emissivity of the conductive oxide. Having a relatively low thermal emissivity means that only a relatively small amount of heat is lost via the radiation of heat in the infrared spectrum. As a result, the coated translucent substrate provides relatively high transmission of light in the PAR spectra range while efficiently blocking NIR and lowering heat transfer via radiation. As such the yield of the greenhouse is improved significantly.

Glass with the conductive oxide coating has been used as glazing in greenhouses for its thermal insulating properties because it has a lower thermal emissivity compared to uncoated glass. However, it is flawed because of significant lower transmission in the PAR spectral range compared to uncoated glass resulting in a much lower production yield. However, a coated translucent substrate with the combination of a conductive oxide coating comprising SnO₂:F and an anti-reflection coating on a layer comprising SnO₂:F has not been manufactured and has not been used as glass for greenhouses. There were no expectations with respect to an additional positive benefit of the combination and as such there was no incentive to combine both types of coatings.

In a further embodiment, the anti-reflection coating is optimized for maximum transmittance of light in a predefined range of light comprising light in a Photosynthetically Active Radiation (PAR) spectral range. The optimized anti-reflection coating comprises multiple layers. The thickness of the multiple layers may be chosen such that reflection of the light in a predefined range of light is reduced as much as possible. By means of simulation or experimentation an optimum may be found which is substantially close to a theoretical maximum. This technique is most effective when a part of the PAR spectral range overlaps with the predefined range of light, causing a large amount of light which is required by the crops for photosynthesis to be transmitted into the greenhouse.

In a further embodiment, the materials of the one or more layers of the anti-reflection coating are optimized for obtaining a maximum transmission of light in the pre-defined range of light and/or at the one or more predefined angles of incidence.

In another embodiment, the anti-reflection coating is optimized for maximum transmittance of light in a predefined range of light comprising light in a Photosynthetically Active Radiation (PAR) spectral range by taking into account the refractive index and the thickness of the conductive oxide coating. The anti-reflection coating and the conductive oxide coating may both comprise one or more layers. The combination of all layers may be optimized. This is advantageous because some characteristics of the layers of the conductive oxide coating interact with characteristics of the layers of the anti-reflection coating. Features of the layers that may be optimized include the materials and the thickness of the layers. The optimization may be performed for one or more predefined angles of incidence of the light, for example, for an angle of incidence of 60 degrees, or for diffuse light which combines all angles of incidence. If the anti-reflection coating is optimized with respect to the conductive oxide coating, the maximum light in the PAR spectral range is transmitted into the greenhouse resulting in a good yield.

In another embodiment, the combination of the anti-reflection coating and the conductive oxide coating is optimized for maximum transmittance of light in a predefined range of light comprising light in a Photosynthetically Active Radiation (PAR) spectral range.

In a further embodiment, the optimization is performed with respect to one or more predefined angles of incidence of the light in the predefined range of light. This optimization may be performed such that the transmission of light in the predefined range of light is optimal for a greenhouse. For example, the optimization may be executed for an angle of incidence of 60 degrees, or for all angles of incidence, which represent diffuse light.

On cloudy days diffuse light impinges on the greenhouse. Diffuse light provides light that impinges at all angles of incidence. The inventor has found that the characteristics of translucent substrates measured at an angle of incidence of 60 degrees provide a relative good indication regarding the characteristics of the translucent substrates when used in diffuse light conditions at a greenhouse. Further, the angle of incidence of direct sunlight changes during the day. In regions with many greenhouses, for example, in the Netherlands which is located at a north latitude of about 52 degrees, the average angle of incidence of direct sunlight is between 40 and 70 degrees throughout the year depending on the orientation of the greenhouse and the angle of the roof. The inventor measured the transmission characteristics of the coated translucent substrate at an angle of incidence of 60 degrees. The transmission characteristic in the PAR spectral range at this angle of incidence shows a high improvement. Additionally, the transmission of light in the NIR spectral range decreases much more than expected. Thus, the coated translucent substrate according to the embodiment provides for unexpectedly good characteristics in at least a greenhouse.

In another embodiment, the coated translucent substrate comprises at a second surface of the translucent substrate a second anti-reflection coating for reducing the reflection of light by the coated translucent substrate. The second surface of the translucent substrate is substantially opposite the first surface. Every transition from a first material to a second material, having a different reflective indexes results in reflections of a part of the light. Thus, the interface between the translucent substrate and the ambient may reflect a part of the light in the PAR spectral range as well. Therefore, it is advantageous to provide another anti-reflection coating at the second side of the translucent substrate.

In a further embodiment, the anti-reflection coating is composed of a first stack of at least three layers and/or another anti-reflection coating that is composes of a second stack of at least three layers. The stacks of at least three layers provide good anti-reflection characteristics such that the transmission of light in the PAR spectral range is high. Typically, many commercially used anti-reflection coatings comprise four layers. In another embodiment, the first stack of layers and/or the second stack of layers includes at least four layers. Four layers provide better anti-reflections characteristics and thus a better transmission of light in the PAR spectral range.

In another embodiment, the translucent substrate is a glass substrate and the conductive oxide coating is manufactured with an Atmospheric Pressure Chemical Vapour Deposition process. This process may efficiently be executed immediately after manufacturing the translucent substrate when the translucent substrate is cooling down. The manufactured translucent substrate coated with the conductive oxide coating is cost effective. Further, the conductive oxide coating is resistant against mechanical and chemical influences. This is advantageous for applying the conductive oxide coating on a single translucent substrate and using the translucent substrate outdoors.

In a further embodiment, the translucent substrate is a glass substrate and the first stack of layers and/or the second stack of layers is manufactured by a process which differs from the Atmospheric Pressure Chemical Vapour Deposition process. The anti-reflection coating which comprises at least 3 or 4 layers is typically manufactured with a sputter deposition process, for example, microware sputtering. The sputter deposition process is a well-known, robust and an efficient process to create the first stack of layers and/or the second stack of layers. Furthermore it allows the first side and the second side of the translucent substrate to be coated with the same process with a high accuracy and in which even the thickness of the layers of the first stack and the second stack may differ.

In another embodiment, the translucent substrate is a glass substrate and the conductive oxide coating is manufactured with an Atmospheric Pressure Chemical Vapour Deposition process and the first stack of layers and/or the second stack of layers is manufactured by a process which differs from the Atmospheric Pressure Chemical Vapour Deposition process.

The manufacturing of the conductive oxide coating with the Atmospheric Pressure Chemical Vapour Deposition process is in general executed in a first factory where the translucent substrate is manufactured and is applied to the translucent substrate when the translucent substrate is cooling down. The anti-reflection coating is typically manufactured with a microwave sputter deposition process, which is a complete different process requiring complete different equipment and is typically executed in a second factory where the conductive oxide coating is applied on the translucent substrate. The fact that two completely different processes that are executed in different factories are required to manufacture the coated translucent substrate is a reason why the two coatings have not been combined in the past.

A semi-manufactured product of a translucent substrate comprising the conductive oxide coating is coated with the anti-reflection coating via the sputter deposition process. As discussed above, the Atmospheric Pressure Chemical Vapour Deposition process in a first factory results in a cost effective semi-finished product, and the application of the first stack of layers and/or the second stack of layers in the second factory via an efficient process provides a cost effective coated translucent substrate. The yield improvement may even be such that it only takes several years to earn back the extra costs of the layers of the coatings.

The different manufacturing techniques, which are currently executed in different factories, is one reason the combination has not been done before. Additionally, it has found out that applying an anti-reflection coating manufactured with a sputter deposition process on top of the semi-manufactured product results in the coated translucent substrate with the discussed unique characteristics.

In another embodiment, the first stack of layers and/or the second stack of layers comprises a first layer of TiO₂ which is sandwiched between a first layer of SiO₂ and a second layer of SiO₂. The layers of TiO₂ and SiO₂ may be manufactured accurately and efficiently. The material of the layers have the right characteristics, e.g., their refractive indices, to create an anti-reflection coating on glass. The right combination of successive layers having specific refractive indices and manufactured at a specific thickness results in an anti-reflection coating that reduces the reflection of light as much as possible. It is to be noted that TiO₂ is not the only material which may be used in the anti-reflection coating for the layers which have a high reflective index. Other materials that may be used include: Nb₂O₃, Ta₂O₅, HfO or Si₂N₄.

In a further embodiment, the first stack of layers and/or the second stack of layers include a second layer of TiO₂, wherein the first layer of SiO₂ is sandwiched between the first layer of TiO₂ and the second layer of TiO₂ resulting in a four layer anti-reflection coating. Thus, the layers of the stack of layers include layers of TiO₂ that alternate with layers of SiO₂. In a further embodiment of the coated translucent substrate, the second layer of TiO₂ of the first stack is applied onto a surface of the conductive oxide coating. In a further embodiment of the coated translucent substrate, the second layer of TiO₂ of the second stack is applied to the second surface of the translucent substrate.

In another embodiment, the first side of the translucent substrate is a light input substrate of the coated translucent substrate. Thus, the first side is the side of the coated translucent substrate on which the light impinges on the coated translucent substrate. The thermal resistance of, for example, a glass substrate depends on the conduction of heat by the glass substrate, and the conduction, convection and radiation of heat from the glass surfaces to the adjacent air. The atmospheric conditions in a greenhouse are typically more humid than the atmospheric conditions of the environment of the greenhouse and the conduction, convection and radiation of heat are different on both sides of the glass substrates of the greenhouse. Having the conductive oxide coating at the side at which the light impinges on the coated translucent substrate, i.e. the exterior of the greenhouse, is especially advantageous with respect to the insulation characteristics of the coated translucent substrate.

In a further embodiment, the coated translucent substrate comprises an indicator for indicating the first side of the translucent substrate as the light input substrate of the coated translucent substrate. The coatings are nearly invisible and as such it is difficult for greenhouse construction workers to distinguish the first side from the second side. As discussed above it is advantageous to orient the first side of the translucent substrate towards sky. The indicator assists the greenhouse construction workers to position the coated translucent substrate correctly in the frame of the greenhouse. In another embodiment the indicator is not provided at the first side, but at a second side which is substantially opposite to the first side. The indicator is for indicating the light output substrate.

In another embodiment, the coated translucent substrate comprises an additional translucent substrate separated from the translucent substrate by a gas filled air gap. The coated translucent substrate of this embodiment results in a double glazing configuration which an coated insulation characteristic than a configuration with only a single translucent substrate. The first side of the translucent substrate is facing the air gap and the translucent substrate is the light input substrate for first receiving the impinging light. The thermal resistance of the air gap significantly increases if the conductive oxide coating is facing the air gap. If the conductive oxide coating is positioned in the gas filled air gap and the translucent substrate on which the conductive oxide coating is provided faces toward the impinging light, the insulation characteristic of the coated translucent substrate is improved. Use of the coated translucent substrates according to this embodiment in a greenhouse decreases the loss of heat during the winter by the greenhouse. The coated translucent substrate blocks a substantial part of the light in the NIR spectral range and thereby prevents, especially in the summer, the overheating of the greenhouse by the NIR light in the sunlight. The coated translucent substrate provides a relatively good insulation, especially in the winter, when the greenhouse is heated by means of, for example, fossil fuels. In a further embodiment, the translucent substrate is the light input substrate and may comprise an indicator for indicating which side of the coated translucent substrate has to be oriented towards the impinging light.

In another embodiment, the second translucent substrate comprises a third surface and a fourth surface. The third surface is facing the air gap and the fourth surface is substantially opposite the third surface. A further anti-reflection coating is applied to the third surface and/or the fourth surface for reducing the reflection of light by the third surface and/or the fourth surface. The further anti-reflection coating prevents the reflection of light, by the further translucent substrate. In a further embodiment, the further anti-reflection coating is optimized for maximally transmitting light in a further predefined range of light comprising light in a Photosynthetically Active Radiation (PAR) spectral range. The optimized further anti-reflection coating better prevents the reflection of light in the PAR spectral range. As discussed in other embodiments, the features of the layers that may be optimized are the materials and the thickness of the layers. The optimization may be performed for one or more predefined angles of incidence of the light, for example for an angle of incidence of 60 degrees, or for diffuse light which combines all angles of incidence.

According to a second aspect of the invention, a greenhouse is provided having one or more coated translucent substrates according to the first aspect of the invention. The greenhouse which is provided with the coated translucent substrates provides a higher yield. The coated translucent substrates substantially block the light in the NIR spectrum, which prevents too much heating of the greenhouse by sunlight, while still allowing the transmission of light in the PAR spectral range into the greenhouse. The preventing of too much heating of the greenhouse results in the prevention of unnecessary ventilation and as such in the prevention of unnecessary loss of carbon dioxide which is used by the crops to grow. Thus, the production yield of the greenhouse is higher than the production yield of greenhouses with normal glass substrates. Further, some crops, for example peppers (capsicums), are very sensitive to NIR light in direct sunlight because NIR light may burn the crops. Blocking a substantial part of the NIR light prevents the burning of the crops.

The greenhouse comprises a roof and at least one wall. The roof includes one or more coated translucent substrates which include one or more coated translucent substrates comprising a single translucent substrate. The wall includes at least one or more coated translucent substrates including two translucent substrates separated by an air gap. The wall with one or more coated translucent substrates provides a better insulation, good PAR light transmission characteristics and substantially good blocking of light in the NIR spectral range. Only minor structural changes are required in the walls to support the higher weight of double glazing because the walls are supported by the ground. The roof provides advantageous PAR light transmission characteristics and a substantially good blocking of NIR light, without the requirement to change the roof supporting structure to support the higher weight of double glazing.

According to a third aspect of the invention, a freezer is provided that comprises a door with a substantially transparent substrate. The substantially transparent substrate comprises the coated translucent substrate according to the first aspect of the invention. The freezer may, for example, be used in shops to present frozen product to potential customers. The coated translucent substrate transmits substantially all light in the spectral range which is visible to the human eye. The colors which may be seen by the human eye substantially overlaps with the PAR spectral range. Further, the coated translucent substrate substantially blocks the near infrared light such that the interior of the freezer does not unnecessary heat up from near infrared light.

In another embodiment, a refrigerator comprises a door with a substantially transparent substrate. The substantially transparent substrate comprises the coated translucent substrate according to the first aspect of the invention.

These and other aspects of the invention are apparent from and will be elucidated with reference to the embodiments described hereinafter.

It will be appreciated by those skilled in the art that two or more of the above-mentioned embodiments, implementations, and/or aspects of the invention may be combined in any way deemed useful.

Modifications and variations to the coated translucent substrate, which correspond to the described modifications and variations of the coated translucent substrate, can be carried out by a person skilled in the art on the basis of the present description.

### BRIEF DESCRIPTION OF THE DRAWINGS

In the drawings:

FIG. 1 shows a cross sectional view of an coated translucent substrate according to the preferred embodiment of the invention,

FIG. 2 shows a cross-sectional view of a coated translucent substrate of another preferred embodiment of the invention,

FIG. 3a shows the transmission characteristics at zero degrees angle of incidence of various embodiments of the present invention,

FIG. 3b shows the transmission characteristics at 60 degrees angle of incidence of various embodiment of the present invention,

FIG. 4 shows a cross-sectional view of a coated translucent substrate according to another preferred embodiment of the invention,

FIG. 5 shows a cross sectional view of a greenhouse according another embodiment of the invention, and

FIG. 6 shows a perspective view of a freezer according to another embodiment of the invention.

### DETAILED DESCRIPTION

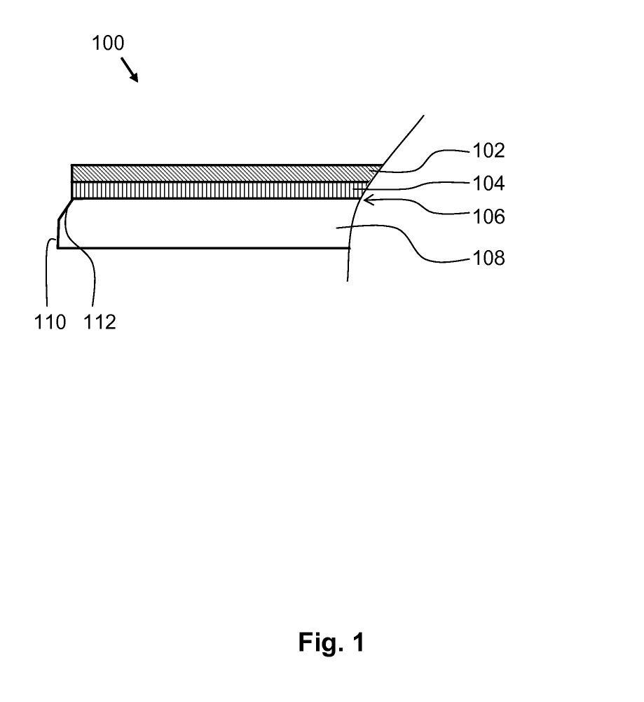

A first embodiment is shown in FIG. 1. A cross-cut of a part of a coated translucent substrate 100 is shown. The coated translucent substrate 100 comprises a translucent substrate 108 which has a first surface 106. On the first surface 106 is applied a conductive oxide coating 104 on which is provided a multilayer anti-reflection coating 102. As shown, at least one of end faces 110 of the translucent substrate 108 is beveled resulting in a beveled portion 112 of the end face 110.

The translucent substrate 108 may, for example, be made of glass. Furthermore, the translucent substrate 108 may be diffuse or fully transparent.

The conductive oxide coating 104 blocks at least a part of the light in the Near Infrared (NIR) spectrum and the anti-reflection coating 102 reduces the reflection of light, especially light in the Photosynthetically Active Radiation (PAR) spectral range. The coated translucent substrate 100 has good transmission characteristics of light in the PAR spectrum and blocks a large amount of light in the NIR spectral range. Therefore, the coated translucent substrate 100 is a very effective solution for the substrates of a greenhouse to increase the yield of the greenhouse: the crops receive a lot of light in the PAR spectrum and the greenhouse does not receive too much light in the NIR spectral range and as such the greenhouse does not heat up too much. Unnecessary ventilation as well as unnecessary loss of carbon dioxide is prevented.

The beveled portion 112 of the end face 110 provides the users of the coated translucent substrate 100 an indictor to indicate the first surface 106 of the translucent substrate 108. It is it is advantageous, especially in greenhouses, to position the first surface 106 towards the sun because the coated translucent substrate 100 provides better insulation characteristics in such a configuration. Thus, light impinging the coated translucent substrate 100 only enters the translucent substrate after passing through the anti-reflection coating 102 and passing through the conductive oxide coating 104.

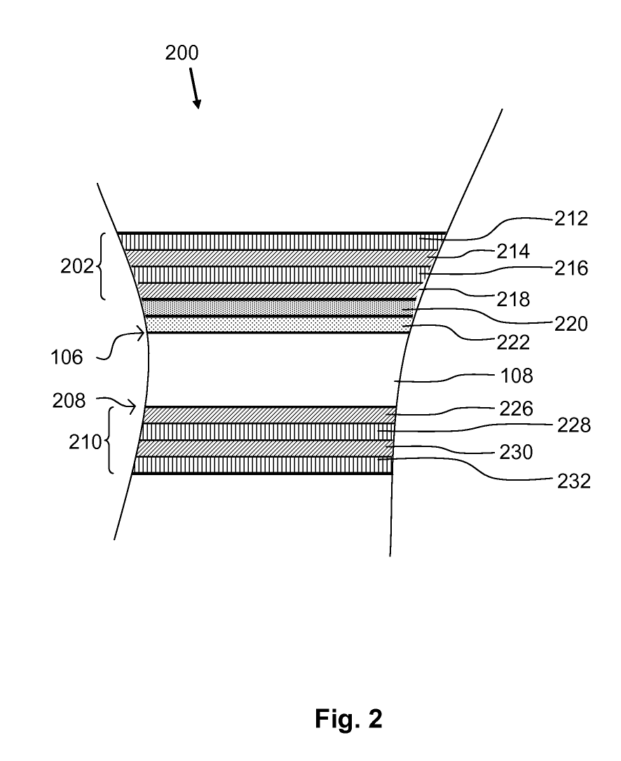

FIG. 2 schematically shows a cross-cut of a part of another embodiment of the first aspect of the invention. A coated translucent substrate 200 is shown which is manufactured on basis of a translucent substrate 108. The translucent substrate 108 has a first surface 106 and a second surface 208 which is substantially opposite the first surface 106. A first stack 202 of layers 212, 214, 216, 218 is an anti-reflection coating. A second stack 210 of layers 226, 228, 230, 232 is another anti-reflection coating. A base layer 222 is applied directly on the first surface 106. In between the first stack 202 and the base layer 222 is interposed a conductive oxide coating 220.

The first stack 202 and the second stack 210 comprise layers 214, 218, 226, 230 of TiO₂ and layers 212, 216, 228, 232 of SiO₂. The base layer 222 is a layer of porous SnO₂. The conductive oxide coating is a layer of SnO₂:F.

All interfaces between the air and the coated translucent substrate 200 are provided with the anti-reflection coatings. This prevents the reflection of light. The conductive oxide coating 220 blocks a substantial part of the light in the NIR spectral range. The thickness of the layers 212, 214, 216, 218 of the first stack 202 is optimized for maximally reducing the reflection of light in the PAR spectral range. The optimization of the layer 212, 214, 216, 218 of the first stack 202 is performed for diffuse light and the characteristics of the conductive oxide coating 220 are taken into account in the optimization. The thickness of the layers 226, 228, 230, 232 of the second stack 210 is optimized for maximally reducing the reflection of light in the PAR spectral range by the second surface 208 of the translucent substrate 108. The thicknesses of the layers 212, 214, 216, 218 of the first stack 202 differ from the thicknesses of the layers 226, 228, 230, 232 of the second stack 210 because the optimization of the first stack 202 takes into account the characteristics of the conductive oxide coating 220 on which the first stack 202 is applied.

In table 1, which is presented below, the materials of all the layers shown in FIG. 2 are listed.

TABLE 1
materials of the layers of the translucent substrate 100

| Layer | Material |
|---|---|
| 212 | SiO₂ |
| 214 | TiO₂ |
| 216 | SiO₂ |
| 218 | TiO₂ |
| 220 | SnO₂:F |
| 222 | SnO₂ |
| 108 | glass |
| 226 | TiO₂ |
| 228 | SiO₂ |
| 230 | TiO₂ |
| 232 | SiO₂ |

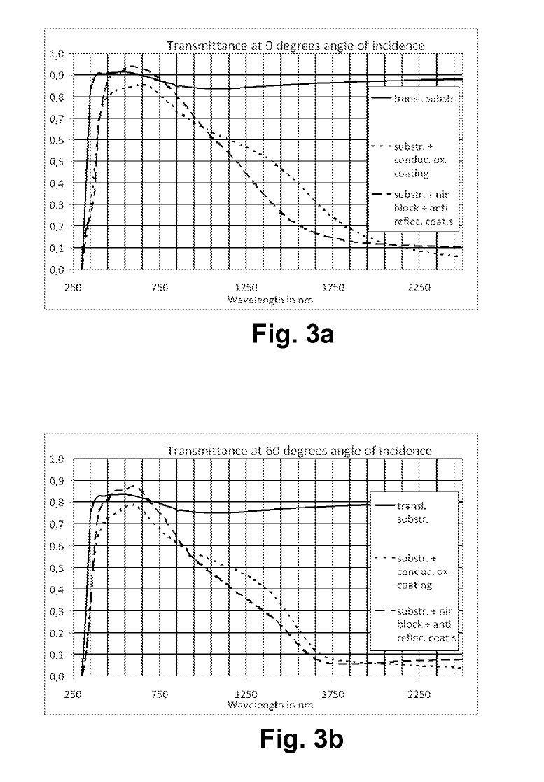

FIG. 3a and FIG. 3b show that the coated translucent substrate 200 has advantageous transmission characteristics. In FIG. 3a and in FIG. 3b, measurements of the transmission of light through the coated translucent substrate 200 are shown. FIG. 3a shows the measurements in which the light impinges on the coated translucent substrate at zero degrees angle of incidence. FIG. 3b shows the light transmission characteristics of light that impinges on the coated translucent substrate at 60 degrees angle of incidence.

The continuous line shows the transmission characteristic of clear glass. Today, most of the greenhouses still use clear uncoated glass. The dotted line shows the transmission characteristics of glass with only the base layer of porous SnO₂ and the conductive oxide coating of SnO₂:F. The dashed line represents the transmission characteristics of the coated translucent substrate as discussed with respect to FIG. 2. On the y-axis the normalized transmission is drawn. The Photosynthetically Active Radiation (PAR) spectral range is roughly from 400 to 700 nanometers. The near infrared (NIR) spectral range is roughly from 800 to 2500 nm.

As may be seen in FIGS. 3a and 3b, the coated translucent substrate 200 is significantly better with respect to the transmission of light in the PAR spectral range, and significantly better with respect to the blocking of light in the NIR spectral range. It is to be noted that the characteristics are not only better when compared to glass with the conductive oxide coating, but also better than clear glass. Thus, if a greenhouse is constructed with the coated translucent substrate 200 instead of clear glass, the transmission of light in the PAR spectral range into the greenhouse will be better and most of the light in the NIR spectral range will be blocked.

The transmission of light in the PAR spectral range of the coated translucent substrate 200 is substantially better than the transmission of light in the PAR spectral range by glass with only the base layer and the conductive oxide coating. Thus, in the PAR spectral range the anti reflection coatings provide an improvement of the transmission and as such a reduction of the reflection and absorption. The transmission of light in the NIR spectral range is much lower for the coated translucent substrate 200 than the transmission of light in the NIR spectral range for glass with only the base layer and the conductive oxide coating. Thus, the anti reflection coatings increases the reflection and absorption of light in the NIR spectral range.

The effect of better PAR light transmission and more NIR light blocking for light impinging at 60 degrees is advantageous for greenhouses. As discussed before, the 60 degrees angle of incidence well represents the characteristics of diffuse light impinging the coated translucent substrate, and the average angle of incidence of direct sunlight is close to 60 degrees angle of incidence.

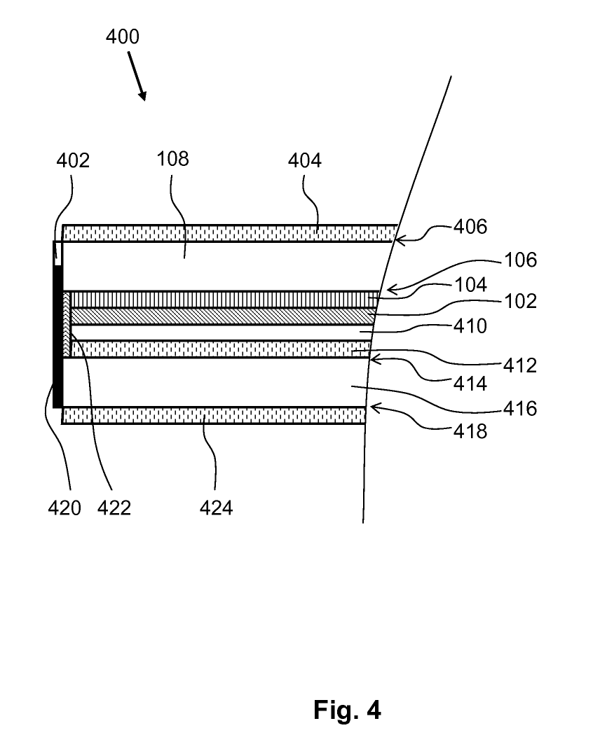

FIG. 4 schematically shows another embodiment of the invention. A cross-cut of a part of a double glazing substrate 400 is shown. At the left end of FIG. 4 the end face of the double glazing substrate is shown. At the right end of FIG. 4 the cross-cut is cut-off, but the double glazing substrate 400 continues further. The double glazing substrate 400 comprises a first translucent substrate 108 and a second translucent substrate 416. The first translucent substrate 108 and the second translucent substrate 416 are separated by an air gap 410 which is filled with a gas, for example argon. At the circumference of the double glazing substrate 400 a spacer 422 is provided to separate the first translucent substrate 108 from the second translucent substrate 416. Further, at the left end is provided a seal 420, for example, made of silicon, for sealing the end faces of the double glazing substrate 400 and to keep the air gap 410 air tight.

The first translucent substrate 108 has a first surface 106 which is facing the air gap 410. A conductive oxide coating 104 is provided on top of the first surface 106 whereon an anti-reflection coating 102 is applied. The anti-reflection coating is optimized for transmitting light in the PAR spectral range and is optimized with respect to the characteristics of the conductive oxide coating 104. The first translucent substrate 108 has a second surface 406 which is substantially opposite the first surface 106. On the second surface 406 is applied another anti-reflection coating 404. The anti-reflection coating 404 is optimized for transmission of light in the PAR spectral range.

The second translucent substrate 416 has a third surface 414 which is facing the air gap 410 and has a fourth surface 418 which is substantially opposite the third surface 414. The third surface 414 and the fourth surface 418 are coated with another anti-reflection coatings 412, 424. Anti-reflection coating 412, 424 have the same characteristics of as the another anti-reflection coating 404.

In the embodiment of FIG. 4 the air gap 410 is air tightly sealed, however, in the embodiment of the double glazing substrate 400 it is not necessary to seal the air gap 410 air tight. The conductive oxide coating 104 and the anti-reflection coatings 102, 412 do not react with air or fluids in the air and as such the air gap 410 may be filled with air and air may flow in or flow out the air gap 410. However, the amount of air that flows in and out the air gap 410 has to be limited in order to maintain the thermal insulation characteristic of the double glazing substrate 400.

The double glazing substrate 400 provides a good light transmission. The anti-reflection coatings 102, 404, 412, 424 prevent the reflection of light, especially in the PAR spectral range. The conductive oxide coating 104 blocks a substantial part of the light in the NIR spectral range and the effect of blocking light in the NIR spectral range is amplified by the anti-reflection coating 102. Thus, the combined effect of the anti-reflection coatings 102, 404, 412, 424 and the conductive oxide coating 104 is that light in the PAR spectral range is well transferred through the double glazing substrate 400 and a significant amount of light in the NIR spectral range is blocked. Further, the double glazing substrate 400 is a good insulator. The air gap functions as an insulator and not much heat may transfer from the second surface 406 towards the fourth surface 418, and vice versa.

A part 402 of the seal 420 has another color. The part 402 of seal 420 is closest to the first translucent substrate 108. Thus, the part 402 of another color indicates which translucent substrate of the double glazing substrate 400 comprises the conductive oxide coating 104 and as such the users of the double glazing substrate 400 learn from the part 402 of the another color how the double glazing substrate 400 has to be positioned in a substrate frame. Especially, when used in greenhouses, it is advantageous to position the double glazing such that light impinging the greenhouse first passes the first translucent substrate 108 with the conductive oxide coating 104 before the light is transferred towards the second translucent substrate 416. A part of the near infrared light may be absorbed by the conductive oxide coating 104. The absorption of the part of the near infrared light results in heating up the conductive oxide coating 104. The air gap 410 prevents the conduction of this heat towards the second translucent substrate 412 and as such the heat does not enter the greenhouse.

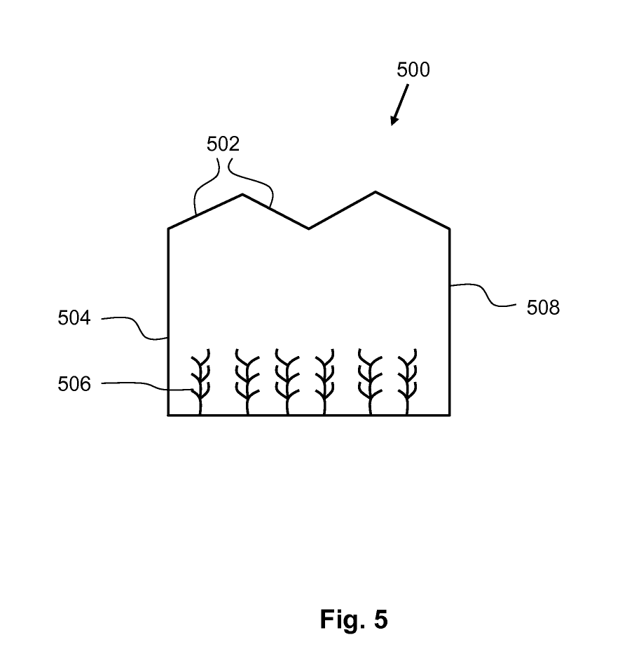

FIG. 5 schematically shows a cross-cut of a greenhouse 500. The greenhouse is used to grow crops 506 and the greenhouse is constructed of walls 504, 508 and has a roof 502. The walls 504, 508 and the roof 502 are constructed of a frame and glass substrates and the frame supports glass substrates. In order to allow as much as possible light entering the greenhouse, most surfaces of the walls 504, 508 and the roof 502 consist of the glass substrates and the frame is constructed such that it does not block much of the light that impinges on the greenhouse.

In one embodiment the glass substrates of the walls 504, 508 and the roof 502 are single substrates of coated translucent substrates. The coatings on the translucent substrates are, from the translucent substrate outward, the conductive oxide coating and the anti-reflection coating. In another embodiment, the coated translucent substrate further comprises on a second side of the coated translucent substrate another anti-reflection coating. The second side is substantially opposite the first side. Using the single substrates is advantageous because it allows a relatively light-weight frame for the greenhouse because of the relative low weight of the single glass substrates.

In another embodiment the glass substrates of the walls 504, 508 are double substrates of two coated translucent substrates which are separated by an air gap. One of the two coated translucent substrates comprises on a first surface a conductive oxide coating and an anti-reflection coating. Another anti-reflection coating may be provided on a second surface of the one of the two coated translucent substrates. The other one of the two coated translucent substrates may comprise, on a third surface and a fourth surface, the another anti-reflection coating as well. The roof 402 of the greenhouse 500 comprises single substrates of an coated translucent substrate according to the first aspect of the invention. It is advantageous to use double substrates in the walls because of the better insulation characteristics of the double substrates. The costs of the greenhouse 500 do not increase dramatically by using double substrates only in the walls 504 and 508, because it is relatively easy to construct the walls 504, 508 with a support structure that is able to support the weight of the double substrates.

In one embodiment, the roof 502 and the walls 504, 508 of the greenhouse comprise only the double substrates as discussed above.

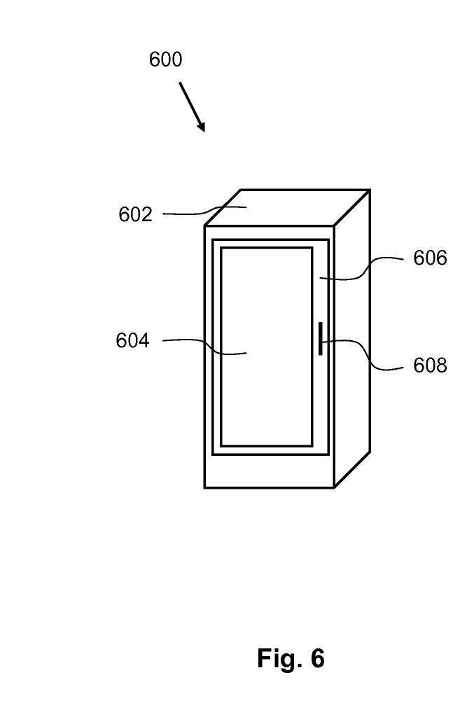

FIG. 6 shows a freezer 600 which is used for storing frozen product in a shop and presenting the frozen product to potential customers. The freezer 600 has a housing 602 which has a freezer door 606 in a front wall of the housing 602. The freezer door 606 may be opened by customer with handle 608. The freezer door 606 further comprises a substantially transparent substrate 604. The substrate 604 is manufactured of an coated translucent substrate according to the first aspect of the invention. The coated translucent substrate comprises at least a first translucent substrate on which at least a conductive oxide coating is manufactured whereon an anti-reflection coating is provided. The coated translucent substrate may further comprise a second translucent substrate which is separated from the first translucent substrate by an air gap.

The freezer is efficient and provides the customers a good view into the freezer. The combination of the conductive oxide coating and the anti-reflection coating reflect a substantial part of the light in the NIR spectral range, which would otherwise unnecessarily heat up the interior of the freezer. Further, the freezer substrate 604 transmits most of the light in visible spectrum. And, if the freezer substrate 604 is manufactured of the first translucent substrate and the second translucent substrate, which are separated by an air gap, the freezer substrate has very good insulation characteristics.

Although the description above and accompanying drawings contains much specificity, the details provided should not be construed as limiting the scope of the embodiments but merely as providing illustrations of some of the presently preferred embodiments. The drawings and the description are not to be taken as restrictive on the scope of the embodiments and are understood as broad and general teachings in accordance with the present invention. While the present embodiments of the invention have been described using specific terms, such description is for present illustrative purposes only, and it is to be understood that modifications and variations to such embodiments, including but not limited to the substitutions of equivalent features, materials, or parts, and the reversal of various features thereof, may be practiced by those of ordinary skill in the art without departing from the spirit and scope of the invention.

1. A coated translucent substrate comprising:
a translucent substrate having a first surface at a first side of the translucent substrate;
an anti-reflection coating at the first side of the translucent substrate for reducing the reflection of light by the coated translucent substrate; and
a conductive oxide coating disposed between the first surface of the translucent substrate and the anti-reflection coating for reducing the transmission of light in the near infrared spectrum through the coated translucent substrate.

2. The coated translucent substrate of claim 1, wherein the conductive oxide coating comprises SnO₂:F.

3. The coated translucent substrate of claim 2, wherein the anti-reflection coating is applied to the conductive oxide coating and wherein the anti-reflection coating comprises multiple layers.

4. The coated translucent substrate according to claim 1, wherein the anti-reflection coating is optimized for a maximum transmittance of light in the Photosynthetically Active Radiation spectral range.

5. The coated translucent substrate according to claim 1, wherein the refractive index and the thickness of the conductive oxide coating are optimized for a maximum transmittance of light in the Photosynthetically Active Radiation spectral range.

6. The coated translucent substrate according to claim 4, wherein the anti-reflection coating is optimized with respect to one or more predefined angles of incidence of the light in the Photosynthetically Active Radiation spectral range.

7. The coated translucent substrate according to claim 1, wherein the coated translucent substrate includes a second surface having a second anti-reflection coating for reducing the reflection of light by the translucent substrate, wherein the second surface is substantially opposite the first surface.

8. The coated translucent substrate according to claim 7, wherein the anti-reflection coating includes a first stack of at least three layers.

9. The coated translucent substrate according to claim 7, wherein the second anti-reflection coating includes a second stack of at least three layers.

10. The coated translucent substrate according to claim 7, wherein the translucent substrate is a glass substrate;
wherein the conductive oxide coating is manufactured with an Atmospheric Pressure Chemical Vapour Deposition process; and
wherein the first stack of layers and the second stack of layers are manufactured by a process which differs from the Atmospheric Pressure Chemical Vapour Deposition process.

11. The coated translucent substrate according to claim 7, wherein the first stack of layers and the second stack of layers each includes a first layer of TiO₂ disposed between a first layer of SiO₂ and a second layer of SiO₂.

12. The coated translucent substrate according to claim 11, wherein the first stack of layers and the second stack of layers each includes a second layer of TiO₂, wherein the first layer of SiO₂ is disposed between the first layer of TiO₂ and the second layer of TiO₂ resulting in a four layer anti-reflection coating.

13. The coated translucent substrate according to claim 12, further comprising an indicator for indicating the first side of the translucent substrate as the light input substrate of the coated translucent substrate.

14. The coated translucent substrate according to claim 1, further comprising a second translucent substrate separated from the translucent substrate by a gas filled air gap.

15. The coated translucent substrate according to claim 14, wherein the second translucent substrate includes a third surface and a fourth surface;
wherein the third surface is facing the air gap and the fourth surface is substantially opposite the third surface;
wherein a further anti-reflection coating is applied to the third surface and the fourth surface for reducing the reflection of light by the third surface and the fourth surface.

16. A greenhouse comprising a plurality of coated translucent substrates, wherein said coated translucent substrates include:
a translucent substrate having a first surface at a first side of the translucent substrate;
an anti-reflection coating at the first side of the translucent substrate for reducing the reflection of light by the coated translucent substrate; and
a conductive oxide coating arranged between the first surface of the translucent substrate and the anti-reflection coating for reducing the transmission of light in the near infrared spectrum through the coated translucent substrate.

17. A door for a freezer, having a transparent substrate, said transparent substrate including:
a translucent substrate having a first surface at a first side of the translucent substrate;
an anti-reflection coating at the first side of the translucent substrate for reducing the reflection of light by the coated translucent substrate; and
a conductive oxide coating arranged between the first surface of the translucent substrate and the anti-reflection coating for reducing the transmission of light in the near infrared spectrum through the coated translucent substrate.

18. A process for manufacturing a coated translucent substrate, comprising the steps of:
applying a base layer to a first surface of a translucent substrate;
applying an anti-reflection coating to the base layer; and
applying a first stack to the anti-reflection coating;
wherein the first stack includes:
a layer selected from the group consisting of TiO₂ Nb₂O₃, Ta₂O₅, HfO and Si₂N₄ disposed between two layers of SiO₂.

19. The process of claim 18, wherein the layer selected from the group is TiO₂ and the stack includes an additional layer of TiO₂.

20. The process of claim 18, wherein the base layer is a conductive oxide coating.

21. The process of claim 20, wherein the conductive oxide coating and the anti-reflection coating are applied substantially parallel to the first surface and cover the entire first surface.

22. The process of claim 18, further comprising the step of optimizing the anti-reflection coating for a maximum transmittance of light in the Photosynthetically Active Radiation spectral range.

23. The process of claim 18, wherein the conductive oxide coating is SnO₂:F.

24. The process of claim 18, wherein the conductive oxide coating is applied with an Atmospheric Pressure Chemical Vapor Deposition process.

25. The process of claim 24, wherein the first stack is applied using a process other than an Atmospheric Pressure Chemical Vapor Deposition process.

26. The process of claim 18, wherein the translucent substrate is glass.

27. The process of claim 18, wherein the conductive oxide coating is applied to the translucent substrate when the translucent substrate is cooling.

28. The process of claim 18, wherein the anti-reflection coating is applied by a microwave sputter deposition process.

29. The process of claim 18, further comprising the step of applying an indicator to first side of the coated translucent substrate.

30. The process of claim 18, further comprising the step of applying a gas filled air gap.

31. The process of claim 18, further comprising the steps of:
applying a second base layer to a second surface of the translucent substrate;
applying a second anti-reflection coating to the second base layer; and
applying a second stack to the second anti-reflection coating;
wherein the second stack includes:
a layer of TiO₂ disposed between two layers of SiO₂.
